(19) United States
(12) Patent Application Publication
(10) Pub. No.: US 2018/0150595 A1
(43) Pub. Date: May 31, 2018

(54) Asset Configuration System

(71) Applicant: Computational Systems, Inc., Knoxville, TN (US)

(72) Inventor: Anthony J. Hayzen, Knoxville, TN (US)

(73) Assignee: Computational Systems, Inc., Knoxville, TN (US)

(21) Appl. No.: 15/362,901

(22) Filed: Nov. 29, 2016

(51) Int. Cl. G06F 17/50; G06Q 10/08

(52) U.S. Cl. CPC G06F 17/5086; G06F 3/04842; G06Q 10/087

(57) ABSTRACT

A method, program, and computerized system for creating a data structure of a virtual model of an asset. A computer includes a processor, storage module, user interface module, display module, and software that when executed by the processor implements the following steps. The system receives a designation of an asset type, and presents simplified diagrammatic shapes of an asset based at least in part upon the asset type. The system presents a selection of specification data entry fields, where the selection is based at least in part on the asset type, and receives specifications in regard to the asset type, as guided by the selection of specification data entry fields. The system associates assets one to another into a data structure, and stores a non-transitory copy of the data structure as the virtual model.

### FIELD

This invention relates to the field of industrial engineering. More particularly, this invention relates to modeling and tracking asset configurations.

### INTRODUCTION

Industrial environments have grown very complex. Many such plants include hundreds or thousands of pieces of equipment, such as motors, couplers, intermediate equipment, and driven equipment, together with sensors and instruments to monitor their behavior and functions, just to name a few.

Keeping track of such assets has become commensurately complex. Not only is there a need to track the location and function of all of the assets in the plant, but there is also a need to track the location and function of all of the sensors that are placed on the equipment.

What is needed, therefore, is a system that helps meet needs such as these, at least in part.

### SUMMARY

The above and other needs are met by a method, program, and computerized system for creating a data structure of a virtual model of an asset. A computer includes a processor, storage module, user interface module, display module, and software that when executed by the processor implements the following steps. The system receives from the user through the user interface module a designation of an asset type, and presents to the user on the display module simplified diagrammatic shapes of an asset based at least in part upon the user-selected asset type. The system presents a selection of specification data entry fields, where the selection is based at least in part on the asset type, and receives from the user through the user interface module specifications in regard to the asset type, as guided by the selection of specification data entry fields. The system associates assets specified by the user one to another as specified by the user into a data structure, and stores on the storage module a non-transitory copy of the data structure as the virtual model.

In various embodiments, the asset type includes at least one of a motor, coupling, gearbox, pump, roller, and turbine. In some embodiments, the simplified diagrammatic shapes include at least one of shafts, bearings, gears, and vanes. In some embodiments, the selection of specification data entry fields includes at least one of number input fields, radio buttons, checkboxes, and drop down lists. In some embodiments, the simplified diagrammatic shapes include selectable indicators for locations of sensors. In some embodiments, the specification data entry fields are dynamically linked to a selection of detailed dialog boxes for data entry and editing, and the selection of detailed dialog boxes is based at least in part on what the user has entered into the specification data entry fields. In some embodiments, the system causes a change that is made to one asset to automatically cause a change in an associated asset.

### DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a flow chart for a method according to an embodiment of the present invention.

FIG. 2 is a data entry screen for defining a machine train according to an embodiment of the present invention.

FIG. 3 is a data entry screen for defining a driver component of a machine train according to an embodiment of the present invention.

FIG. 4 is a data entry screen for defining sensor locations for a driver component of a machine train according to an embodiment of the present invention.

FIG. 5 is a data entry screen for defining a coupling between two of a driver component, an intermediate component, and a driven component of a machine train according to an embodiment of the present invention.

FIG. 6 is a data entry screen for defining a first intermediate component of a machine train according to an embodiment of the present invention.

FIG. 7 is a data entry screen for defining a second intermediate component of a machine train according to an embodiment of the present invention.

FIG. 8 is a data entry screen for defining a first driven component of a machine train according to an embodiment of the present invention.

FIG. 9 is a data entry screen for defining a second driven component of a machine train according to an embodiment of the present invention.

FIG. 10 is a data entry screen for defining a third driven component of a machine train according to an embodiment of the present invention.

FIG. 11 is a functional block diagram of a computerized system according to an embodiment of the present invention.

### DESCRIPTION

### Basic System

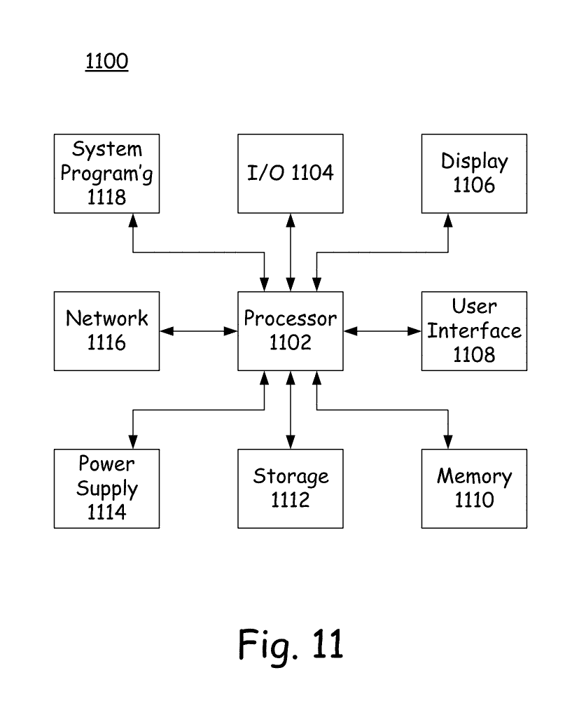

With reference now to FIG. 11 there is depicted a functional block diagram of a computer system 1100 according to an embodiment of the present invention. The system 1100 comprises modules as described below, which modules are comprised of both hardware and software structures. The system 1100 includes at least one processor 1102 for computational capabilities and for control of the other modules of the system 1100. In some embodiments, the processor 1102 comprises more than one of a variety of different types of computational or control modules, such as mathematical computation units, graphics processors, specialized processors, and so forth. The processor 1102 is in data communication with the other modules of the system 1100.

Some embodiments of the system 1100 also one or more include input/output modules 1104, such as ports of various kinds, including for example serial ports, parallel ports, USB ports, and specialized data ports. The I/O module 1104 provides transfer of data into and out of the system 1100. Some embodiments of the system 1100 include at least one display 1106, such as flat panel, projection, or holographic displays. The display module 1106 provides visual representations to the user. The system 1100 includes, in some embodiments, one or more user interface modules 1108, such as keyboards, mice, pens, touchscreens, biometrics, touchpads, and drawing pads. The user interface module 1108 enables a user to input data into the system 1100.

The system 1100 also includes, in some embodiments, at least one memory module 1110, such as random access memory, in which data and programs can be loaded, operated upon, run, edited, and so forth. In some embodiments the memory module 1110 includes transitory memory media. Some embodiments of the system 1100 include one or more storage modules 1112, such as floppy disks, hard disks, disk arrays, optical disks, and so forth. In some embodiments the storage module 1112 includes non-transitory media. The storage module 1112 provides the ability for the system 1100 to read and store the data structures (virtual models) as described herein, and to read programming and preconfigured data for asset configuration.

The system 1100 also includes a power supply module 1114 in some embodiments, such as a battery or battery array or conditioning modules for receipt of power from an external power supply, thus providing power as required by the various other modules of the system 1100. Some embodiments of the system 1100 include one or more network modules 1116, such as modules for wireless or wired communication with other computing systems or networks of such, according to one or more of a variety of protocols, such as Ethernet. Some embodiment of the system 110 also include system programming modules 1118, which include specialized programming for the operation of the system 1100 as described herein. In some embodiments these system programming modules 1118 are disposed in one or more of the memory 1110 and storage 1112, or at times reside at least partially in such. In other embodiments the system programming modules 1118 are separate from the memory modules 1110 and the storage modules 1112.

### Overview

According to various embodiments of the present system 1100, there is described a computer system 1100 with a user interface for creating a data structure comprising a computerized model of the assets in a plant, such as a manufacturing facility, power generation facility, and so forth. The various data elements of the data structure represent physical pieces of equipment (including elements such as machines, devices, instruments, monitors, tools, and sensors), as described in more detail below, including the type of equipment, the position, the relationship with other pieces of equipment, the function, and so forth. When accessed by the system 1100, the data structure enables the system 1100 to present diagrammatic shapes, such as block diagrams, of the physical and other aspects of the equipment. These representations allow users, such as industrial engineers, technicians, and others, to locate and monitor the operation of the equipment.

In addition, these block diagrams assist the user in identifying where the sensors that monitor the equipment are placed and what type of measurements are to be taken, all of which is included in the data structure that is produced by the system 1100. The diagrams are further dynamically linked by the system 1100 to detailed configuration dialog boxes, thereby simplifying information entry for the user. In other words, the system 1100 presents dialog boxes to the user that walk the user through the process of defining these highly complex physical systems, and constructing the data structure of the computerized model of the physical systems.

The system 1100, together with various extensions, is used to manage plant assets, including their configuration, which is required for monitoring the assets with a range of devices such as vibration, process, and other sensors. The configuration of these sometimes-complex assets can be a challenge for those who design or maintain them. In order to simplify this process, a series of simple block diagrammatic shapes have been designed to aid the user in setting up these assets for detailed configuration.

To illustrate this process, the present example describes plant rotating machine assets that are typically monitored using vibration analysis devices and tools. The basic concept of asset diagrams is not limited to rotating machine assets, but can be applied to a broad range of assets in a plant, such as valves, heat exchanges, electrical panels, and so forth.

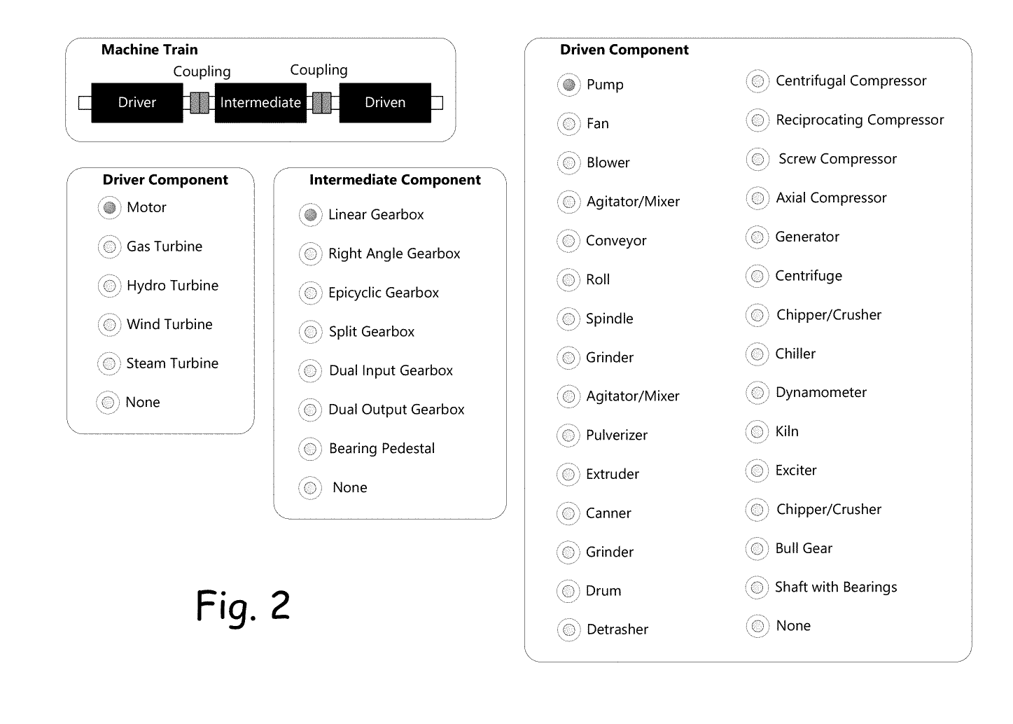

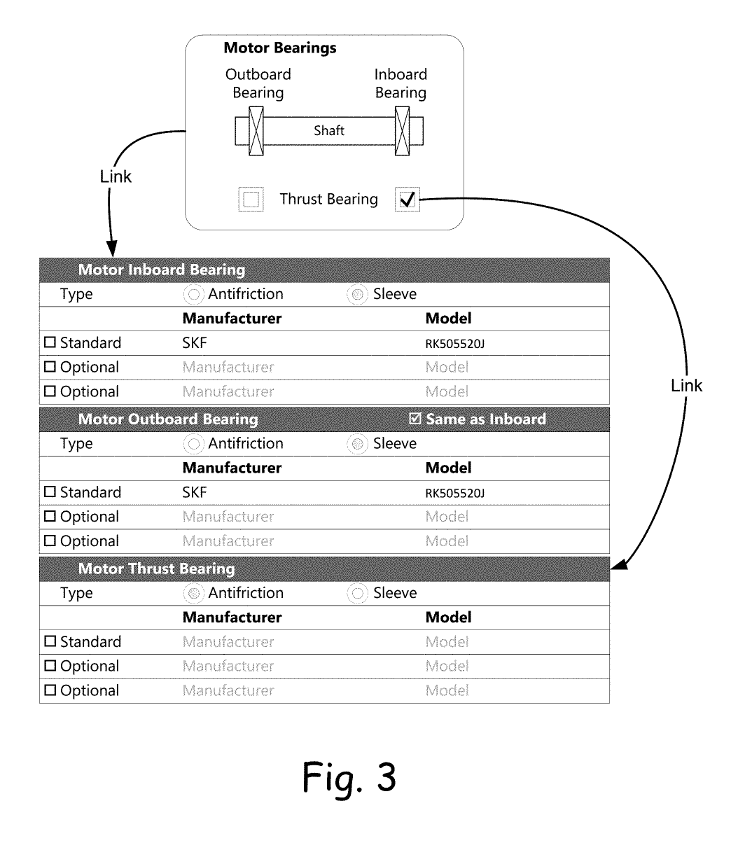

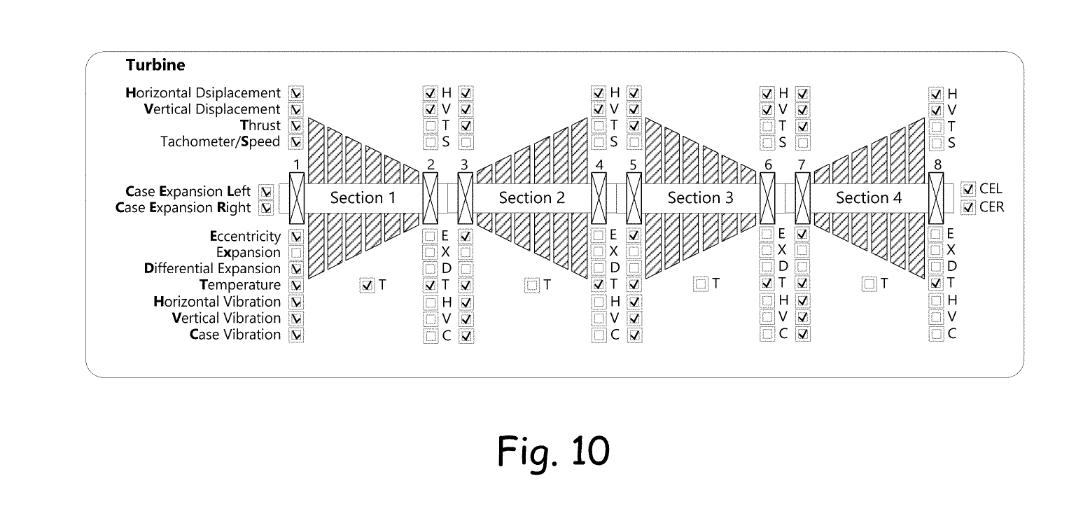

As a part of this process, a machine train is virtually constructed, such as depicted in FIG. 2. Machine trains typically consist of a driver, intermediate components, and driven components, all connected by couplings. The detailed configuration of each of these components and couplings can be quite complex. The configuration diagrams (represented in the data structure) that represent them are illustrated in FIGS. 3 through 10. These diagrams range from a relatively simple motor (FIG. 3) to a very complex turbine (FIG. 10). This list of diagrammatic shapes is only a sample of the possibilities, and the concept can easily be extended to include machines such as paper machines, shovels, draglines, and very complex components such as epicyclic gearboxes.

The virtual construction of the machine train in the data structure can be accomplished at different points in time. For example, the virtual construction of the machine train can be accomplished prior to the time that the actual, physical machine train is constructed, such as in a planning phase of the facility. In another embodiment, the virtual construction of the machine train can be accomplished after the actual, physical machine train is constructed.

The concept of the diagrams representing the fundamental parts of a component such as shafts, bearings, gears, and so forth is further extended to indicate where the component is to be monitored, such as by presenting on a display 1106 a series of check boxes and radio buttons. The check boxes and radio buttons are dynamically linked to the detailed configuration dialogs that are used to enter the configuration information. These dialog boxes are dynamically adjusted to only show the relevant information, based at least in part on whether a check box is checked.

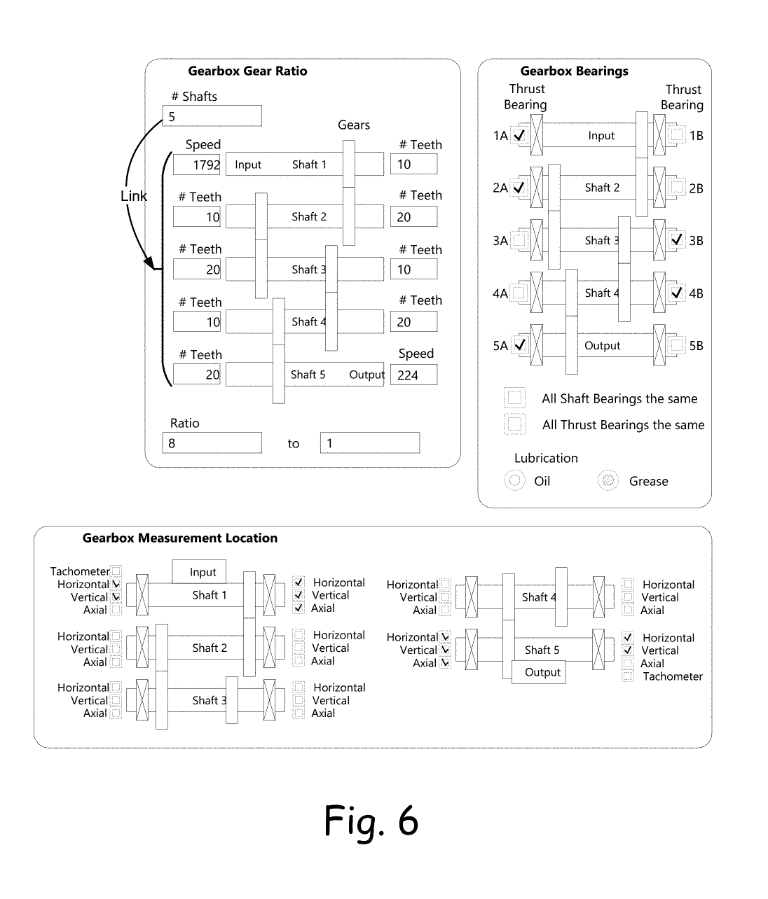

In some cases, such as a gearbox (FIG. 6), the number of shafts in the diagram is also dynamically adjusted, depending upon the number of shafts required. This example also illustrates the feature that multiple diagrammatic shapes can be dynamically linked together, whereby the number of shafts in the bearing diagram is dynamically adjusted to only show the number of shafts with bearings, for example.

The dynamic linking of the checkboxes to the detailed data entry dialog boxes is particularly relevant in a complex component such as a turbine (FIG. 10). As can be seen in this example, only a few of the possible measurement locations are checked and, therefore, the linked dialog box would be greatly reduced in complexity, by only showing the relevant measurement location that require detailed configuration.

Thus, various embodiments of the present invention provide for a computerized system 1100, such as a general-purpose computer running specialized software, that presents generalized depictions of plant equipment to a user. The user uses the configuration tools present in the system 1100, such as radio buttons, sliders, drop-down lists, and blanks, to fill in the information specific to the assets that is currently being described, in a series of windows that are presented to the user for this purpose. By completing the diagrammatic shape description process, the user is able to provide to the system 1100 the details that are necessary for the system 1100 to build a computerized model or data structure representation of even very complex assets, such as machine trains.

### Details

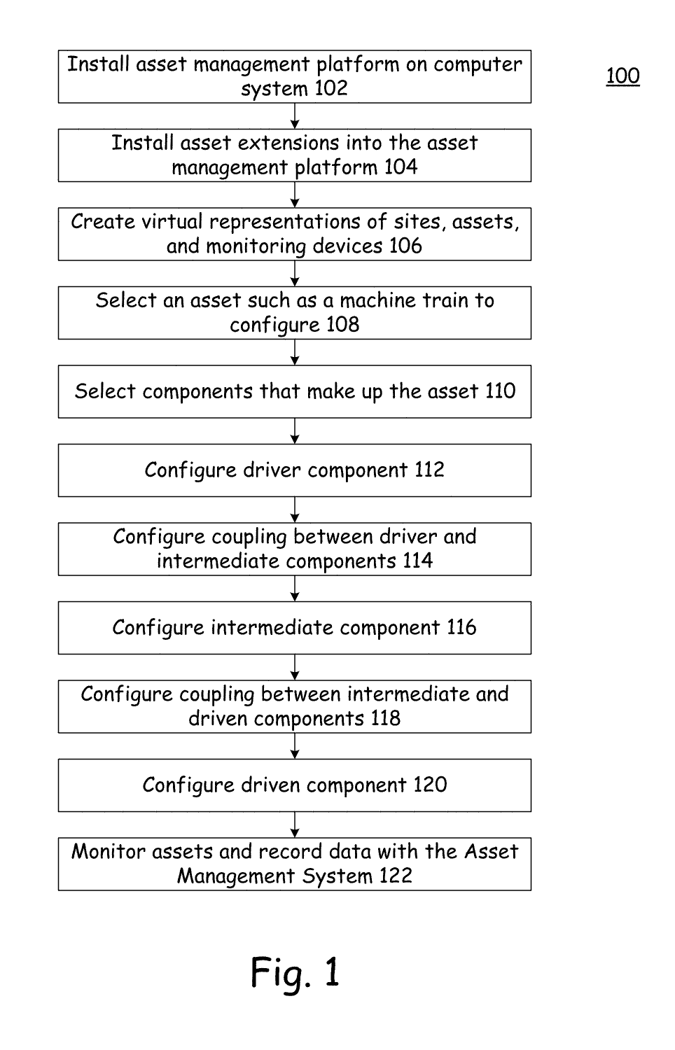

With reference now to FIG. 1, there is depicted a method 100 for constructing the virtual machine train (data structure), according to the presently-described embodiment of the invention. In step 102, the asset management platform (software) is installed on a computer system 1100, such as a personal computer, hand-held computing device, or network of such. The asset extensions are installed into the management system 1100, as given in box 104, which include predefined configuration dialog boxes for various classes or types of assets. The extensions are data structures that represent various real-world, physical components of assets, such as machine trains, in a generic format that can be customized by a user of the system 1100 for specific assets in a plant, as described in more detail below.

As given in block 106, site locations are created in the virtual model, such as represent a specific plant in a specific location—such as a facility at 123 Main Street in Anytown, Ohio, USA. Physical assets and devices that monitor them are also created in the computer system 1100.

An asset to configure, such as the machine train described in the present example, is selected, as given in block 108, and the components that make up the machine train are selected, as given in block 110. This process is described in more detail in regard to FIG. 2. In the present example, the components of the machine train comprise a driving component, an intermediate component, a driven component, a shaft, couplings that fix shafts between these components, and a variety of sensors and monitors at different locations.

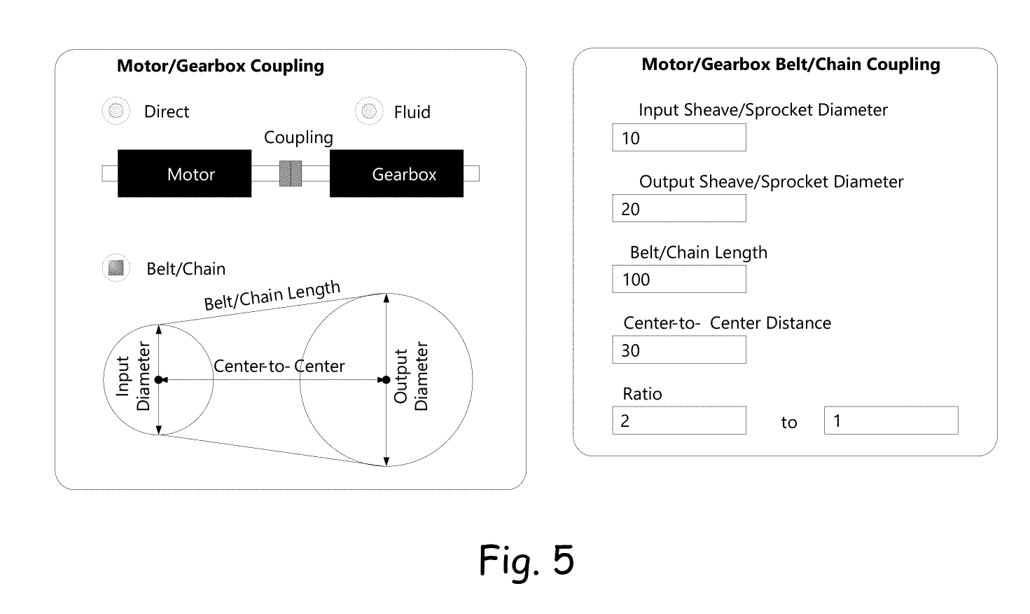

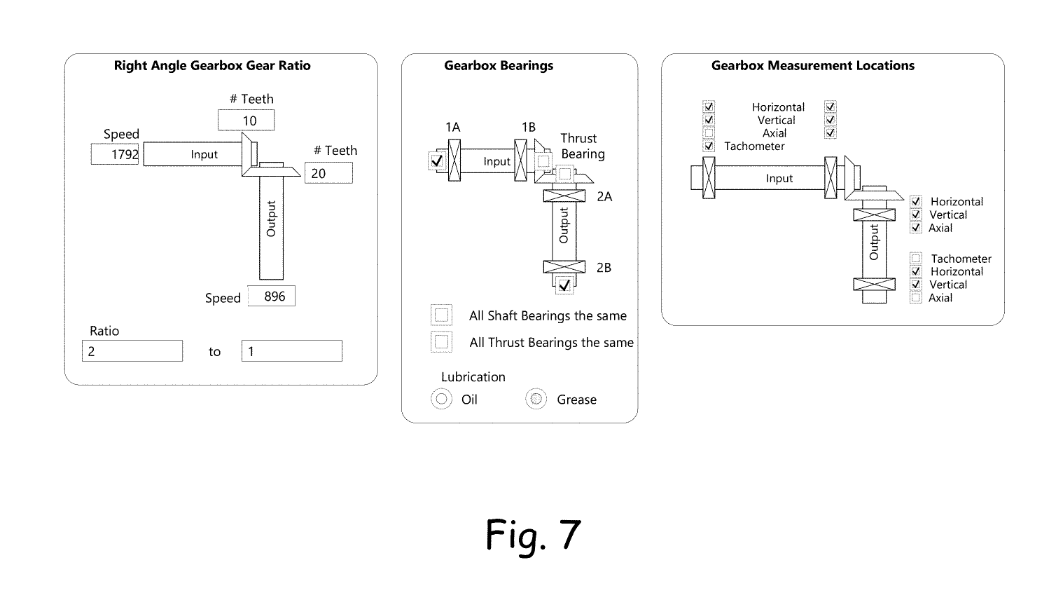

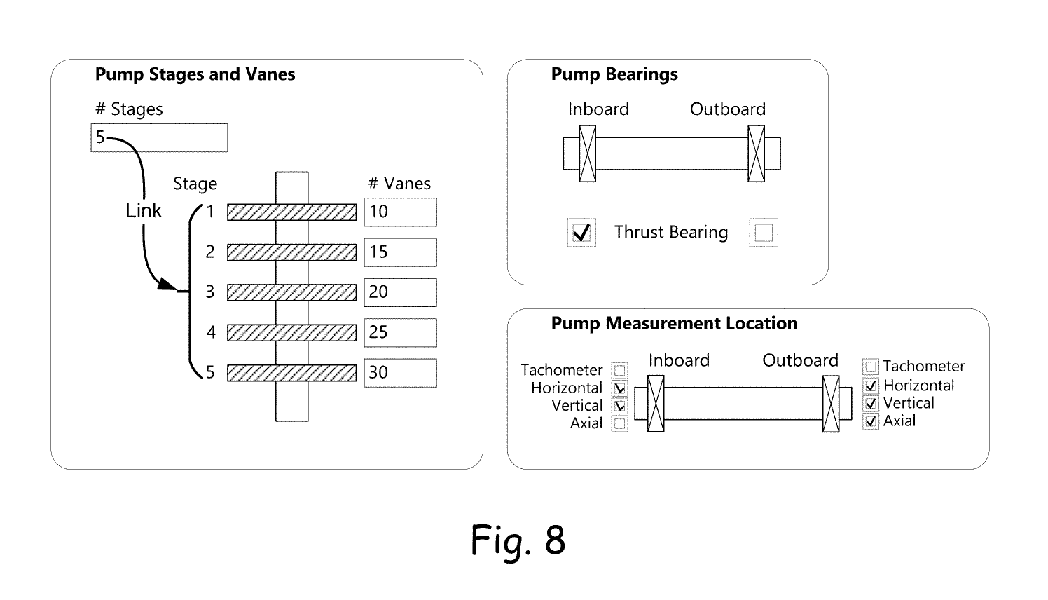

Thus, in the present example, the driver component is configured as given in block 112. This is described in more detail in regard to FIG. 3. The coupling between the driver component and the intermediate component is configured as given in block 114. This is described in more detail in regard to FIG. 5. The intermediate component is configured as given in block 116. This is described in more detail in regard to FIGS. 6 and 7. The coupling between the intermediate and driven components id configured as given in block 118. This is the same process as that described in regard to FIG. 5, although the exact configurations of the couplings used in the machine train need not be the same in all defined instances. The driven component is configured as given in block 120. This is described in more detail in regard to FIGS. 8-10.

Once the physical machine train is constructed (if the model is created prior to construction of the physical machine train), then the sensors and monitoring equipment can be used to collection operational data on the physical asset, which information can be collected and stored by some embodiments of the system 1100, as given in block 122.

### Specific Example

With reference now to FIG. 2, the virtual model (data structure) of the machine train to be monitored is constructed. As introduced above, machine trains typically consist of a driver, intermediate and driven components connected by couplings. While this seems quite straightforward, the detailed configuration of each of these components, couplings, and their associated sensors can be quite complex. However, their constituent elements can be represented by relatively simple block diagrams, such as given in FIGS. 3 through 10. These diagrams range from the relatively simple motor of FIG. 3, to a very complex turbine as represented by FIG. 10. The diagrams in the figures are only a sample of the embodiments of the present system 1100, and various embodiments of the invention can be extended to include machines such as paper machines, shovels, draglines, and even more complex components such as epicyclic gearboxes.

The concept of the block diagram shapes representing the fundamental parts of a component such as shafts, bearings, gears, and so forth is further extended to indicate where the component is to be monitored (where a sensor is to be placed) by using a series of data input devices, such as check boxes, radio buttons, drop down lists, data fields, and so forth. The check boxes and radio buttons are dynamically linked to the detailed configuration dialogs that are used to enter the configuration information, adding and removing various elements of a given component as desired by the user. In some embodiments, these dialog boxes are dynamically adjusted to only show the relevant information, based on whether a check box is checked or not, for example.

In some cases, such as the gearbox of FIG. 6, the number of shafts in the diagram is also dynamically adjusted depending on the number of shafts required. This example also illustrates the feature that multiple diagrams can be dynamically linked together by the system 1100, whereby the number of shafts in the bearing diagram is also dynamically adjusted to only show the required number of shafts with bearings.

The dynamic linking of the checkboxes to the detailed data entry dialog boxes is particularly relevant in a complex component such as the turbine of FIG. 10. As can be seen in this example, only a few of the possible measurement locations are checked, and therefore the linked dialog box would be greatly reduced in complexity, only showing the relevant measurement location that require detailed configuration.

With reference again to FIG. 2, a machine train is depicted with components, namely a driver, an intermediate, a driven, and between each of these components a coupling, which is typically one of a direct coupling, a belt or chain, or fluid, but could include other coupling types. The required components as illustrated in this set of diagrams are selected, such as by using the radio buttons depicted in FIG. 2.

In some embodiments, each of the components and the couplings required specific configuration information, and the following figures depict diagrams that are used to enable easy configuration of the components and couplings. With reference now to FIG. 3, the machine diagram depicted consists of a set of standard building blocks or shapes that represent the various components of a machine, which in this example is a motor (having been specified as such in the diagram of FIG. 2). In this embodiment, the motor is represented in a simplified form as a shaft with two bearings on the shaft, as depicted in FIG. 3. Check boxes are used to indicate whether an end thrust bearing is located on either end of the shaft.

The diagrams as depicted in the figures are dynamically linked in some embodiments to input dialog boxes that only show relevant information from the diagram. For example, it there were no thrust bearings checked, then the thrush bearing input information would not be shown in the dialog box. This simplifies input for users in that they only need to see and enter relevant information. In some embodiments, the input dialog boxes themselves may also be dynamically linked to libraries of information, such as a bearing library, which contains detailed information about each unique bearing being used.

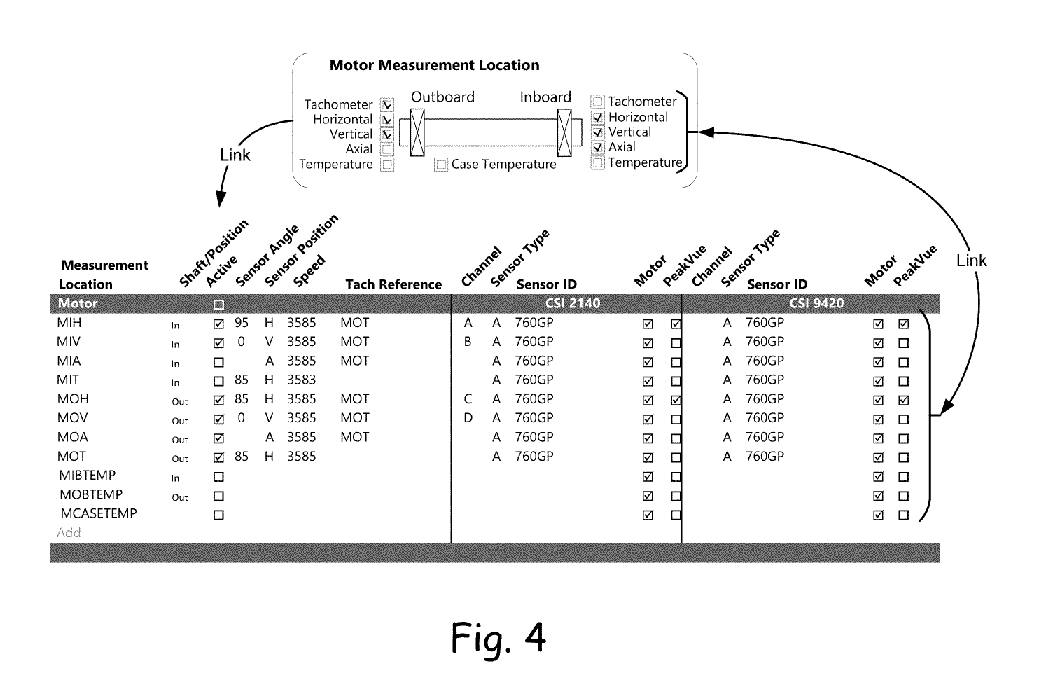

With reference now to FIG. 4, there is depicted a diagram with check boxes that indicate the measurement locations on the motor. In general, the measurement locations represent where a sensor is placed on the machine (which in this case is a motor). Once again, check boxes are dynamically linked to input dialog boxes. In this example of dynamic dialog boxes, all possible measurement locations are shown, but the check boxes are dynamically linked to the table of sensors below, indicating which are checked in the machine diagram above. In other embodiments, only sensor locations indicated in the diagram are present in the table.

In some embodiments the dynamic link works in both directions—meaning that if a check box is checked in the dialog box below, then the matching check box in the machine diagram above is automatically checked. These linkages make it easier for a user to define what measurement locations are active or being used

With reference now to FIG. 5, there is depicted an example of a machine coupling diagram that is not dynamically linked to other diagrams or a dialog box. Its purpose is to illustrate the dialog box user input information, making it easier for a user to understand the meaning of the input fields. If a fluid type coupling is selected, it implies a variable speed coupling. The coupling ratio is calculated from the sheave/sprocket diameters. If diameters are not known, then a coupling ratio can be manually entered.

In some embodiments, the system 1100 receives the input from the user to construct the virtual model, and computes all of the parameters of the coupling based on the input. For example for a direct coupling, the ratio is 1:1. The belt/chain length can either be entered directly or calculated for center-to-center distance and diameters, and vice versa.

With reference now to FIG. 6, the example of a gearbox intermediate component further illustrates the capability of the diagrams, in that the diagrams themselves are dynamically linked and extensible. The step of entering in the number of shafts dynamically creates the number of shafts shown in the diagram. The same number of shafts are also dynamically linked to subsequent gearbox diagrams for bearings and measurement locations. In this embodiment, five shafts are shown. If the user had entered only two shafts, then only two shafts would be shown in the diagrams. This further simplifies the user interface for users, such as by only showing the relevant number of shafts.

In this embodiment, the user also enters the number of teeth on each gear, which enables the calculation of the overall gearbox speed ratio between the input shaft and the output shaft by the system 1100. If the number of teeth on each gear is unknown, then the user may simply enter the gearbox ratio. As in the previous examples, the diagrams are dynamically linked to input dialog boxes. FIG. 7 depicts alternate arrangements for the gearbox intermediary.

With reference now to FIG. 8, there is depicted a representational dialog box for driven component, which in this example is a pump. Similar to the gearbox intermediary example, the diagram for the pump also automatically adjusts according to the number of stages, as input by the user. The step of entering the number of stages dynamically creates the number of stages shown in the diagram. For each stage the number of vanes is entered. Other information in regard to bearings and measurement locations is also entered, similar to that as described above.

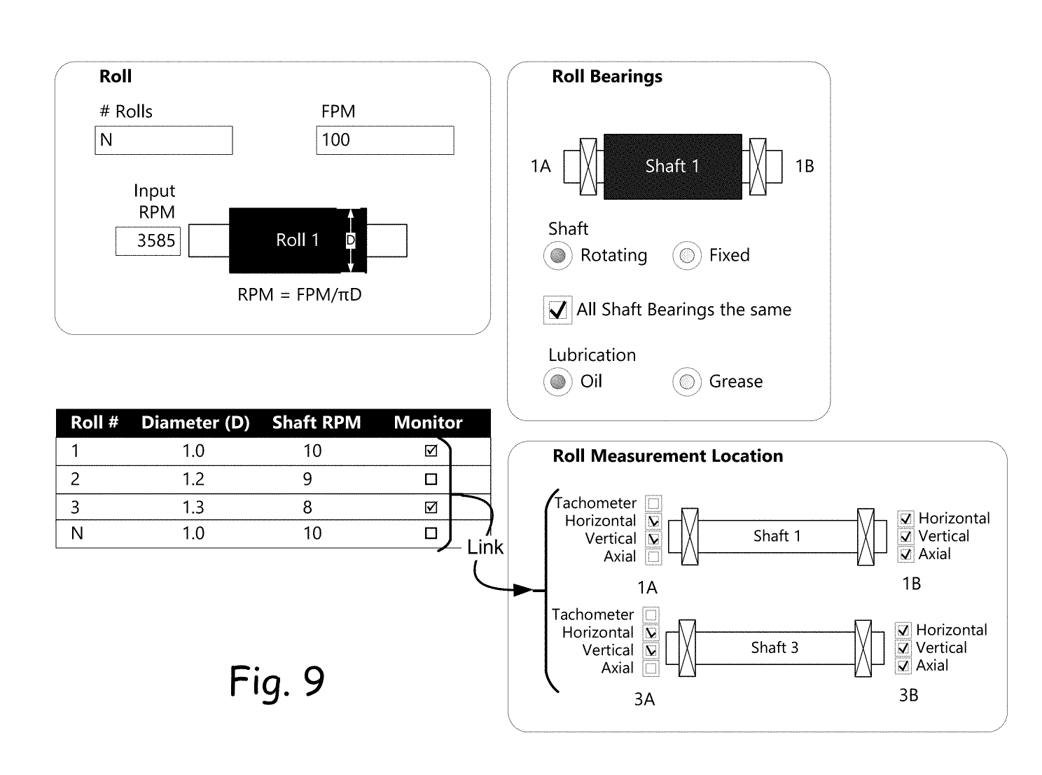

With reference now to FIG. 9, there is depicted another embodiment of a driven component, which is a roller. The number of rollers as entered by the user dynamically generates the applicable number of rows in the linked dialog box. The data entry dialog box is then used to enter, for example, the diameter of each roller. The rotational speed for each roller is automatically calculated by the system 1100 from the feed rate, such as in feet per minute, using information that is linked from other diagrams and input by the user.

Checkboxes on each roller indicate whether the roller is monitored. Measurement locations are dynamically created for each roller that is indicated as being monitored, similar to the dynamic constructions described above in regard to the gearbox intermediates.

With reference now to FIG. 10, there is depicted a driven turbine, which is one of the more complex machines to monitor. The diagrams according to various embodiments of the present invention vastly simplify the monitoring setup and other management aspects for the turbine. As before, the diagram for the driven turbine is dynamically linked to input dialog boxes.

Other examples of diagrams for complex equipment include those for paper machines, drag lines, shovels, epicyclic gearboxes, valves, electrical switch gears, and so forth.

By using the tools described above as provided by the computerized system 1100, a virtual model of an actual machine can be constructed. The virtual model is a data structure, such as can be saved on a non-volatile computer readable medium, that can be stored and used on different systems 1100. For example, such data structures for machines or other assets that are created once according to the processes described above can be saved and reused as desired to represent different instances of similar machines and assets that exist in different facilities around the world.

If the system 1100 as described herein is used to model an asset prior to construction of the actual physical asset, then the system 1100 can be used as a simplified means of designing the asset. For example, by entering different specifications in the data entry boxes for a gearbox, as given in FIG. 6, an engineer can specify the type of gearbox that is desired, given the input and output rotational requirements. If the system 1100 as described herein is used to model an asset after construction of the actual physical asset, then the user inputs the actual specifications of the assets that are being virtually represented.

In this manner, entire complex plants containing many different assets can be virtually modeled, and the data structures so created can be used for the modeling of other plants, and as a detailed record of the location and operation of the various assets. In some embodiments, the system 1100 is in data communication with the sensors and monitors and machines as modeled, and also oversees the collection, storage, and analysis of data from the assets. Other benefits, such as inventory, utility requirements, and depreciation can also be garnered from use of various embodiments of the system 1100 as described herein.

The foregoing description of embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

1. A computerized system for creating a data structure comprising a virtual model of an asset, the system comprising:
a computer comprising a processor, a storage module, a user interface module, and a display module,
software that when executed by the processor implements the following steps,
receives from the user through the user interface module a designation of an asset type,
presents to the user on the display module simplified diagrammatic shapes of an asset based at least in part upon the user-selected asset type, and a selection of specification data entry fields, where the selection is based at least in part on the asset type,
receives from the user through the user interface module specifications in regard to the asset type, as guided by the selection of specification data entry fields,
associates assets specified by the user one to another as specified by the user into a data structure, and
stores on the storage module a non-transitory copy of the data structure as the virtual model.

2. The computerized system of claim 1, wherein the asset type includes at least one of a motor, coupling, gearbox, pump, roller, and turbine.

3. The computerized system of claim 1, wherein the simplified diagrammatic shapes includes at least one of shafts, bearings, gears, and vanes.

4. The computerized system of claim 1, wherein the selection of specification data entry fields includes at least one of number input fields, radio buttons, checkboxes, and drop down lists.

5. The computerized system of claim 1, wherein the simplified diagrammatic shapes includes selectable indicators for locations of sensors.

6. The computerized system of claim 1, wherein the specification data entry fields are dynamically linked to a selection of detailed dialog boxes for data entry and editing, and the selection of detailed dialog boxes is based at least in part on what the user has entered into the specification data entry fields.

7. The computerized system of claim 1, wherein the system causes a change that is made to one asset to automatically cause a change in an associated asset.

8. A program disposed on a non-transitory medium, the program for creating a data structure comprising a virtual model of an asset, that when executed by a processor implements the following steps,
receives from a user through a user interface module a designation of an asset type,
presents to the user on a display module simplified diagrammatic shapes of an asset based at least in part upon the user-selected asset type, and a selection of specification data entry fields, where the selection is based at least in part on the asset type,
receives from the user through a user interface module specifications in regard to the asset type, as guided by the selection of specification data entry fields,
associates assets specified by the user one to another as specified by the user into a data structure, and
stores on a non-transitory medium a copy of the data structure as the virtual model.

9. The program of claim 7, wherein the asset type includes at least one of a motor, coupling, gearbox, pump, roller, and turbine.

10. The program of claim 7, wherein the simplified diagrammatic shapes includes at least one of shafts, bearings, gears, and vanes.

11. The program of claim 7, wherein the selection of specification data entry fields includes at least one of number input fields, radio buttons, checkboxes, and drop down lists.

12. The program of claim 7, wherein the simplified diagrammatic shapes includes selectable indicators for locations of sensors.

13. The program of claim 7, wherein the specification data entry fields are dynamically linked to a selection of detailed dialog boxes for data entry and editing, and the selection of detailed dialog boxes is based at least in part on what the user has entered into the specification data entry fields.

14. The program of claim 7, wherein the system causes a change that is made to one asset to automatically cause a change in an associated asset.

15. A method for creating a data structure comprising a virtual model of an asset, the method comprising the steps of:
receiving a designation of an asset type,
presenting simplified diagrammatic shapes of an asset based at least in part upon the asset type, and a selection of specification data entry fields, where the selection is based at least in part on the asset type,
receiving from specifications in regard to the asset type, as guided by the selection of specification data entry fields,
associating assets one to another into a data structure, and
storing on a non-transitory medium a copy of the data structure as the virtual model.

16. The method of claim 15, wherein the asset type includes at least one of a motor, coupling, gearbox, pump, roller, and turbine.

17. The method of claim 15, wherein the simplified diagrammatic shapes includes at least one of shafts, bearings, gears, and vanes.

18. The method of claim 15, wherein the selection of specification data entry fields includes at least one of number input fields, radio buttons, checkboxes, and drop down lists.

19. The method of claim 15, wherein the simplified diagrammatic shapes includes selectable indicators for locations of sensors.

20. The method of claim 15, wherein the specification data entry fields are dynamically linked to a selection of detailed dialog boxes for data entry and editing, and the selection of detailed dialog boxes is based at least in part on what the user has entered into the specification data entry fields.
